(19) United States
(12) Patent Application Publication
(10) Pub. No.: US 2024/0304238 A1
(43) Pub. Date: Sep. 12, 2024

(54) CACHE DEVICE AND OPERATION METHOD THEREOF

(71) Applicant: MACRONIX International Co., Ltd., Hsinchu (TW)

(72) Inventors: Feng-Min Lee, Hsinchu City (TW); Yu-Yu Lin, New Taipei City (TW)

(73) Assignee: MACRONIX International Co., Ltd., Hsinchu (TW)

(21) Appl. No.: 18/180,145

(22) Filed: Mar. 8, 2023

(51) Int. Cl. G11C 11/4096; G11C 11/4093

(52) U.S. Cl. CPC G11C 11/4096; G11C 11/4093

(57) ABSTRACT

The disclosure provides a cache device, which includes: a first transistor having a control terminal, a first terminal, and a second terminal, in which the first terminal of the first transistor is coupled to an input voltage, and the second terminal of the first transistor is coupled to a storage node; an inverter having an input terminal and an output terminal, in which the input terminal is coupled to the storage node; and a second transistor having a control terminal, a first terminal, and a second terminal, in which the first terminal of the second transistor is coupled to the output terminal of the inverter, and the second terminal of the second transistor is configured to output a read voltage.

### BACKGROUND

Technical Field

The disclosure relates to a memory device, and particularly relates to a cache device.

### Description of Related Art

Dynamic random access memory (DRAM) is an important memory device in the computer hierarchy architecture, which has the characteristics of providing fast access speed, random access feature, high density, etc. However, in the field of big data, the bandwidth, data throughput, and latency between the DRAM and the processor may be the bottleneck for computing performance.

The standalone feature of DRAM components brings the benefits of high density and low cost, but the distance between DRAM components and processors also causes performance bottlenecks.

Therefore, there is a need for fast, low-latency and high-density memory in this technical field. However, the manufacturing process of DRAM components is not compatible with advanced logic manufacturing process. In addition, it is quite expensive to provide a large memory capacity with static random access memory (SRAM). Embedded DRAMs or novel devices for L3/L4 caches have been the focus of attention in this field.

### SUMMARY

Based on the above description, according to an embodiment of the disclosure, a cache device is provided, which includes a first transistor, an inverter, and a second transistor. The first transistor has a control terminal, a first terminal, and a second terminal, in which the first terminal of the first transistor is coupled to an input voltage, and the second terminal of the first transistor is coupled to a storage node. The inverter has an input terminal and an output terminal, in which the input terminal is coupled to the storage node. The second transistor has a control terminal, a first terminal, and a second terminal, in which the first terminal of the second transistor is coupled to the output terminal of the inverter, and the second terminal of the second transistor is configured to output a read voltage.

According to another embodiment of the disclosure, an operation method of a cache device is provided. The cache device includes a first transistor, an inverter, and a second transistor. The first transistor has a control terminal, a first terminal, and a second terminal, in which the first terminal is coupled to an input voltage, and the second terminal is coupled to a storage node. The inverter has an input terminal and an output terminal, in which the input terminal is coupled to the storage node. The second transistor has a control terminal, a first terminal, and a second terminal, in which the first terminal is coupled to the output terminal of the inverter, and the second terminal is configured to output a read voltage. The operation method of the cache device includes the following. During a write period, the first transistor is turned on and the second transistor is turned off, so that the input voltage is stored in the storage node. During a read period, the first transistor is turned off and the second transistor is turned on, and a voltage of the output terminal of the inverter is output as an output voltage through the second terminal of the second transistor.

### BRIEF DESCRIPTION OF THE DRAWINGS

FIG. 1 is a schematic diagram of an example of a cache array configuration according to an embodiment of the disclosure.

FIG. 2 is an example of a cache device according to an embodiment of the disclosure.

FIG. 3 is an example of a relationship diagram of a storage voltage and an output voltage of a cache device according to an embodiment of the disclosure.

FIG. 4 illustrates a schematic diagram of a voltage of a storage node of a cache device with respect to time according to an embodiment of the disclosure.

FIG. 5 illustrates a schematic layout diagram of a cache device according to an embodiment of the disclosure.

FIG. 6 illustrates a schematic layout diagram of a cache device according to another embodiment of the disclosure.

### DESCRIPTION OF THE EMBODIMENTS

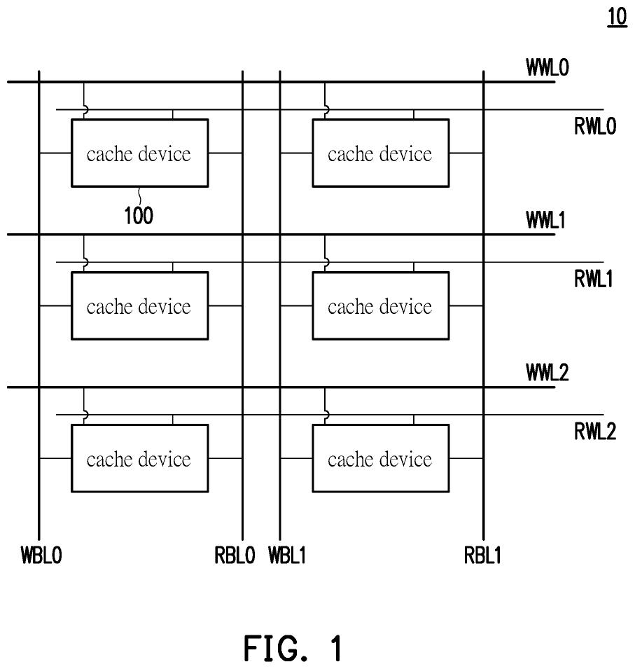

FIG. 1 is a schematic diagram of an example of a cache array configuration according to an embodiment of the disclosure. As shown in FIG. 1, a cache array 10 includes a plurality of cache devices 100 arranged in an array configuration. The cache array 10 includes a plurality of write word lines WWL0 to WWLi, a plurality of write bit lines WBL0 to WBLj, a plurality of read word lines RWL0 to RWLi, and a plurality of read bit lines RBL0 to RBLj. Here, three (i=3) word lines for writing and reading are taken as an example, and two (j=2) bit lines for writing and reading are taken as an example, but the implementation is not limited thereto.

In addition, each cache device 100 is disposed at an intersection of each write word line WWLi and write bit line WBLj and an intersection of each read word line RWLi and read bit line RBLj. In other words, when data is written to each cache device 100, a write bias is applied to the corresponding write word line WWLi and write bit line WBLj, while the corresponding read word line RWLi and read bit line RBLj is not selected (disabled). Also, when data is read from each cache device 100, a read bias is applied to the corresponding read word line RWLi and read bit line RBLj, while the corresponding write word line WWLi and write bit line WBLj is not selected (disabled).

According to an embodiment of the disclosure, the cache device 100 comprises transistors without using capacitors, for example, the cache device 100 is configured in a 4T0C configuration. The specific configuration of the cache device 100 will be further described below. Under this configuration, the cache device 100 is, for example, a 6-terminal device, in which two terminals are coupled to the write word line WWLi and the write bit line WBLj for write operation, two terminals are coupled to the read word line RWLi and the read bit line RBLj for read operation, and two terminals are coupled to voltage sources V_{DD}′ and V_{SS}′ (to provide voltages to an inverter in the cache device 100 as described later).

In an embodiment, word lines WLi (including the write word line WWLi and the read word line RWLi) and bit lines BLi (including the write bit line WBLi and the read bit line RBLj) of the cache array 10 may be arranged as being orthogonal to each other for array layout design.

Next, the configuration of the cache device 100 will be described. FIG. 2 is an example of a cache device according to an embodiment of the disclosure. As shown in FIG. 2, the cache device 100 of the disclosure comprises a first transistor M1, an inverter INV, and a second transistor M2. The cache device 100 may comprises at least 4 transistors, and does not need capacitors as storage units.

As shown in FIG. 2, the first transistor M1 has a control terminal (such as the gate of the first transistor M1 shown in FIG. 2), a first terminal and a second terminal (such as source/drain terminals). The first terminal of the first transistor M1 is coupled to an input voltage. The second terminal of the first transistor M1 is coupled to a storage node SN. According to an embodiment of the disclosure, the first transistor M1 is implemented as a low leakage current transistor. By using the low leakage current transistor M1, a retention time of the storage node SN keeping data may be increased. The low leakage current transistor M1 may adopt low leakage current CMOS transistor, low leakage current IGZO (indium gallium zinc oxide) transistor or other equivalent transistors. A bulk of the low leakage current transistor M1 is coupled to a second power supply voltage V_{SS}′.

The inverter INV may function as buffer for buffering the input voltage V_{DD} or GND of the cache device 100. The inverter INV has an input terminal IN and an output terminal OUT. The input terminal IN of the inverter INV is coupled to the storage node SN. As an example of the inverter INV, as shown in FIG. 2, the inverter INV may comprise a third transistor M3 and a fourth transistor M4 connected to each other in series. The third transistor M3 is, for example, a PMOS transistor, a control terminal thereof (such as the gate of the third transistor M3 shown in FIG. 2) is coupled to the input terminal IN (or the storage node SN) of the inverter INV, the first terminal is coupled to a first power supply voltage V_{DD}′, and the second terminal is coupled to the output terminal OUT of the inverter INV. A bulk of the third transistor M3 is coupled to the first power supply voltage V_{DD}′. The fourth transistor M4 is, for example, an NMOS transistor, a control terminal thereof (such as the gate of the fourth transistor M4 shown in FIG. 2) is coupled to the input terminal IN (or the storage node SN) of the inverter INV, the first terminal is coupled to the output terminal OUT of the inverter INV, and the second terminal is coupled to the second power supply voltage V_{SS}′. A bulk of the fourth transistor M4 is coupled to the second power supply voltage V_{SS}′.

Here, the first power supply voltage V_{DD}′ is greater than the second power supply voltage V_{SS}′. The first power supply voltage V_{DD}′ may be slightly smaller than a first system power supply voltage V_{DD}, and the second power supply voltage V_{SS}′ may be approximately equal to a second system power supply voltage V_{SS} (GND).

The second transistor M2 is, for example, an NMOS transistor. The second transistor M2 has a control terminal (such as the gate of the second transistor M2 shown in FIG. 2), a first terminal and a second terminal (such as source/drain terminals). The first terminal of the second transistor M2 is coupled to the output terminal OUT of the inverter INV. The second terminal of the second transistor M2 is configured to output a read voltage. In addition, the bulks of the first transistor M1 and the second transistor M2 are coupled to the second power supply voltage V_{SS}′ (GND).

According to an embodiment of the disclosure, the first transistor M1 is used as a write transistor. The gate of the first transistor M1 is coupled to the write word line WWL, and the first terminal of the first transistor M1 is coupled to the write bit line WBL to apply the input voltage. In addition, the second transistor M2 is used as a read (access) transistor. The gate of the second transistor M2 is coupled to the read word line RWL, and the second terminal of the second transistor M2 is coupled to the read bit line RBL, and the read voltage is output from the read bit line RBL. According to an embodiment of the disclosure, compared with a general SRAM cache with 6 transistors, only 4 transistors are required in this embodiment and no capacitors is required, so the area cost may be further reduced. In addition, the cache device 100 of the disclosure is, for example, a DRAM-like configuration such as 4T0C, so the cache device 100 may be compatible with CMOS logic operation and speed requirements.

In addition, the cache device 100 of the disclosure may be used to replace the L3/L4 SRAM cache memory in the processor or controller.

Next, the operation of the cache device 100 will be further described. The following description is for one cache device 100 of the cache array 10 shown in FIG. 1.

First, the write operation of the cache device 100 will be described. As shown in FIG. 2, during the writing operation, a unselect bias is applied to the read word line RWL and the read bit line RBL of the selected cache device 100, so as to turn off the read transistor (that is, the second transistor) M2 coupled to the read word line RWL and the read bit line RBL. In addition, a write bias is applied to the write word line WWL and the write bit line WBL of the selected cache device 100, so as to turn on the write transistor (that is, the first transistor) M1 coupled to the write word line WWL and the write bit line WBL. For example, a write voltage is applied to the write word line WWL to turn on the write transistor M1, and a system power supply voltage V_{DD} or a ground voltage GND (or V_{SS}) is applied to the write bit line WBL. At this time, since the write transistor M1 is turned on, a voltage of the storage node SN becomes V_{DD} or GND by applying the system power supply voltage V_{DD} or the ground voltage GND (or V_{SS}) to the write bit line WBL.

Afterward, the write transistor M1 is turned off. At this time, the voltage of the storage node SN may be held at V_{DD} or GND.

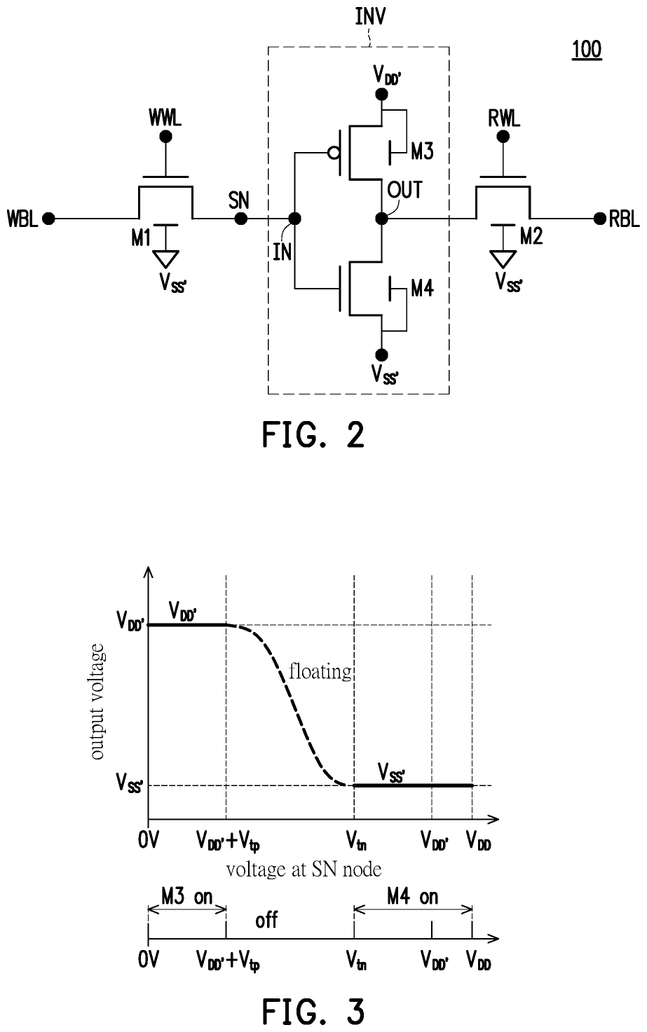

Next, the read operation of the cache device 100 will be described. FIG. 3 is an example of a relationship diagram of a storage voltage and an output voltage of a cache device according to an embodiment of the disclosure. Data stored in the cache device 100 may be read within a retention time of the data of the cache device 100. During the read operation, the read transistor M2 is turned on, for example, a select voltage is applied to the read word line RWL. Also, the write transistor M1 is turned off during the read operation. When the read transistor M2 is turned on, a voltage of the read bit line RBL may be increased to V_{DD}′ or V_{SS}′ (GND), which depends on the voltage held at the storage node SN.

Referring to FIG. 2 and FIG. 3 at the same time, assuming that threshold voltages of the third transistor M3 and the fourth transistor M4 are Vtp and Vtn, respectively. For the third transistor M3 of the inverter INV, if a voltage (the voltage of the storage node SN) applied to the gate thereof is smaller than V_{DD}′+Vtp (in which the threshold voltage Vtp is a negative value), then the third transistor M3 is turned on. For example, the second power supply voltage V_{SS}′ (GND) is applied to the write bit line WBL, so that the voltage of the storage node SN becomes the voltage V_{SS}′ (GND, V_{SS}), and the voltage of the storage node SN is smaller than V_{DD}′+Vtp. In this case, the output terminal OUT of the inverter INV becomes the first power supply voltage V_{DD}′. Therefore, during the read period, when the read transistor M2 is turned on, the voltage of the read bit line RBL is increased to the voltage V_{DD}′. Thus, the voltage V_{DD}′ may be read from the cache device 100. In other words, when the input voltage (the voltage of the storage node SN) is smaller than V_{DD}′+Vtp, the voltage V_{DD}′ may be output.

In addition, for the fourth transistor M4 of the inverter INV, if a voltage (the voltage of the storage node SN) applied to the gate is greater than Vtn, then the fourth transistor M4 is turned on. For example, the first power supply voltage V_{DD}′ is applied to the write bit line WBL, so that the voltage of the storage node SN becomes the voltage V_{DD}′, and the voltage V_{DD}′ at the storage node SN is greater than Vtn. In this case, the output terminal OUT of the inverter INV becomes the second power supply voltage V_{SS}′ (GND). Therefore, during the read period, when the read transistor M2 is turned on, the voltage of the read bit line RBL is decreased to the voltage V_{SS}′. Thus, the voltage V_{SS}′ may be read from the cache device 100. In other words, when the input voltage (the voltage of the storage node SN) is greater than Vtn, the voltage V_{SS}′ may be output.

In addition, when the input voltage (the voltage of the storage node SN) is between the voltage V_{DD}′+Vtp and the voltage Vtn, then an output of the cache device 100 is in a floating state. In addition, the first power supply voltage V_{DD}′ applied to the third transistor M3 of the inverter INV has to be smaller than the voltage |Vtp|+Vtn, so that a current path from the first power supply voltage V_{DD}′ to the second power supply voltage V_{SS}′ through the transistors M3 and M4 is closed. In addition, the first power supply voltage V_{DD}′ may be smaller than the first system power supply voltage V_{DD}, so as to ensure that the relationship of V_{DD}′<|Vtp|+Vtn may be established. In addition, the voltage at the storage node SN may be greater than the first power supply voltage V_{DD}′, such as the first system power supply voltage V_{DD}, to obtain a longer retention time.

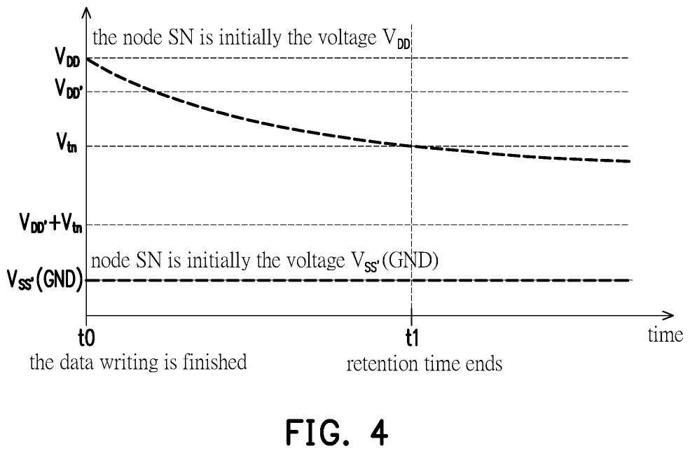

FIG. 4 illustrates a schematic diagram of a voltage of a storage node of a cache device with respect to time according to an embodiment of the disclosure. As shown in FIG. 4, the ordinate represents the voltage of the storage node SN, the abscissa represents the time, t0 represents a time point when the data writing of the cache device 100 finishes, and te represents a time point when a retention time of stored data of the cache device 100 ends.

When the voltage held at the storage node SN is initially the first system power supply voltage V_{DD}, that is, during a write period of the cache device 100, the first system power supply voltage V_{DD} is applied to the write bit line WBL. At the time point t0, after the data writing is finished, the voltage V_{DD} held at the storage node SN starts to discharge from the voltage V_{DD} to the voltage V_{SS}′. During the discharge period, when the voltage of the storage node SN reaches the threshold voltage Vtn, the fourth transistor M4 of the inverter INV is turned off, and then the output voltage becomes the voltage V_{SS}′ (GND). When the voltage of the storage node SN is smaller than the threshold voltage Vtn, the retention of the cache device 100 is caused to fail, and the output voltage becomes floating.

In addition, when the voltage held at the storage node SN is initially the second system power supply voltage V_{SS}′(GND), the voltage of the storage node SN is held at GND, the third transistor M3 of the inverter INV is turned on, and the fourth transistor M4 is turned off. At this time, the output voltage becomes the voltage V_{DD}′.

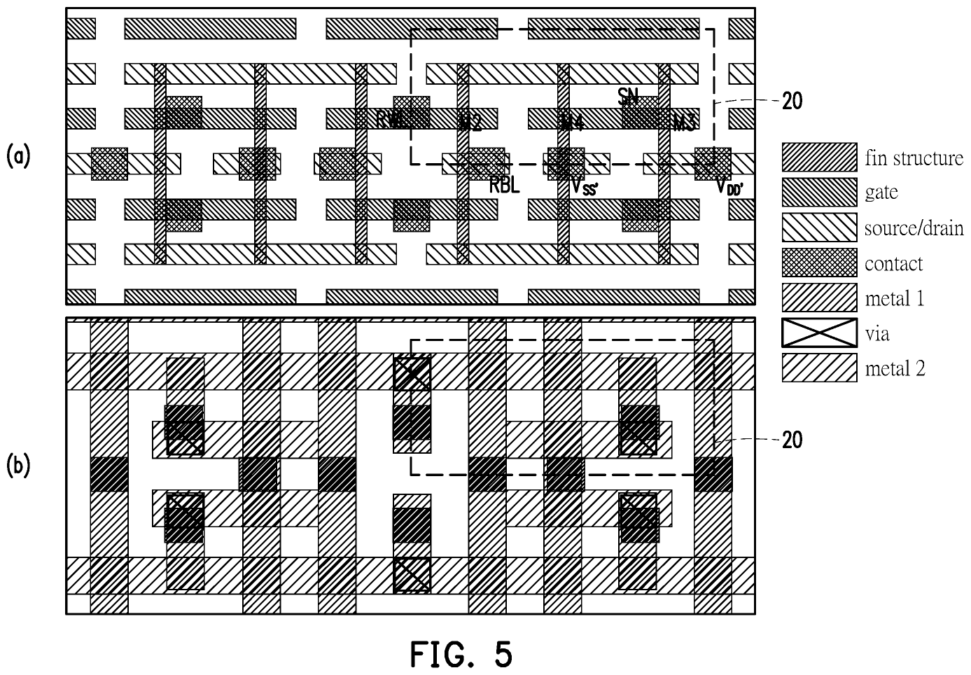

FIG. 5 illustrates a schematic layout diagram of a cache device according to an embodiment of the disclosure. FIG. 5 is a schematic layout diagram adopting a fin field effect transistor (FinFET). (a) in FIG. 5 is an example of three transistors M2, M3, and M4 (refer to FIG. 2) of a unit memory cell 20 (that is, corresponding to the cache device 100 in FIG. 2) of the cache memory. In addition, (b) in FIG. 5 is an example that the low leakage current transistor M1 of the cache device 100 may adopt an IGZO transistor (i.e., the transistor M1) in a back end of line (BEOL) manufacturing process. The IGZO transistor may be connected to the storage node SN through another via structure. In this example, only 3 transistors are required in a layout area of the cache device 100 of the disclosure, and the other one is completed in the BEOL manufacturing process. Therefore, compared with a 6T SRAM cache memory, the area size of the unit memory cell 20 may be further reduced.

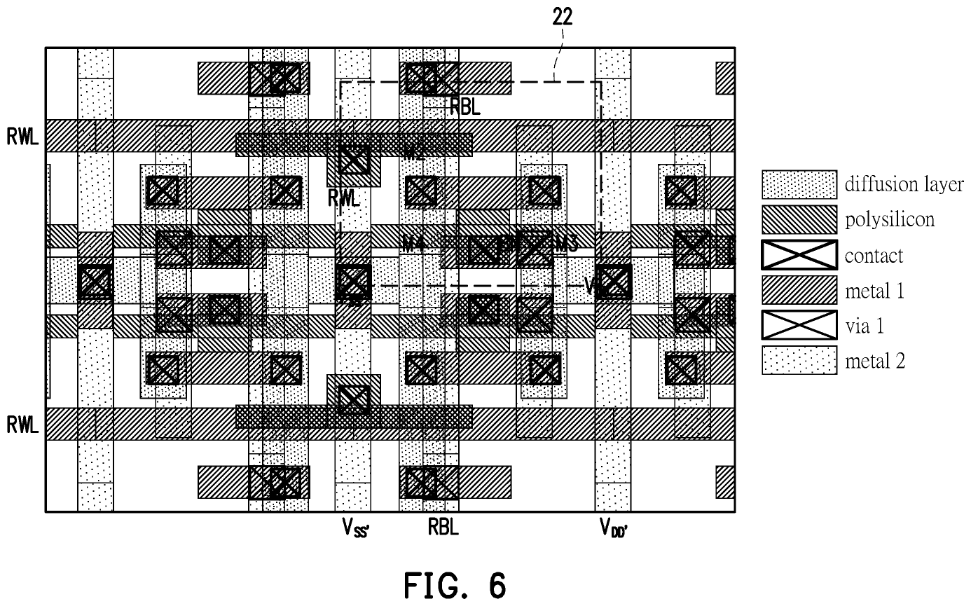

FIG. 6 illustrates a schematic layout diagram of a cache device according to another embodiment of the disclosure. The layout architecture shown in FIG. 6 is a configuration adopting a planar transistor. Under this configuration, all four transistors (M1 to M4) of the cache device 100 may be formed on one plane. In addition, three transistors (M2 to M4) may also be formed on the plane, and the other low leakage current transistor M1 (such as using the IGZO transistor) is completed by the BEOL manufacturing process. In this case, a drift layer is 20% smaller than the SRAM memory. Therefore, compared with the 6T SRAM cache memory, the area size of a unit memory cell 22 may be further reduced.

Based on the above description, according to the cache device of the embodiment of the disclosure, in which a DRAM architecture of 4 transistors and no capacitor (4T0C) is used to construct the cache device. The cache device may be compatible with DRAM manufacturing process, logic operation, and speed requirements. In addition, the cache device may reduce the layout area, thereby increasing the memory capacity and reducing the cost.

What is claimed is:

1. A cache device, comprising:
a first transistor having a control terminal, a first terminal, and a second terminal, wherein the first terminal of the first transistor is coupled to an input voltage, and the second terminal of the first transistor is coupled to a storage node;
an inverter having an input terminal and an output terminal, wherein the input terminal is coupled to the storage node; and
a second transistor having a control terminal, a first terminal, and a second terminal, wherein the first terminal of the second transistor is coupled to the output terminal of the inverter, and the second terminal of the second transistor is configured to output a read voltage.

2. The cache device according to claim 1, wherein the first transistor is a low leakage current transistor.

3. The cache device according to claim 2, wherein the first transistor is used as a write transistor, the control terminal of the first transistor is coupled to a write word line, and the first terminal of the first transistor is coupled to a write bit line to apply the input voltage,
the second transistor is used as a read transistor, the control terminal of the second transistor is coupled to a read word line, and the second terminal of the second transistor is coupled to a read bit line to output the read voltage.

4. The cache device according to claim 1, wherein the inverter comprises:
a third transistor having a control terminal, a first terminal, and a second terminal, wherein the control terminal of the third transistor is coupled to the input terminal of the inverter, the first terminal of the third transistor is coupled to a first power supply voltage, and the second terminal of the third transistor is coupled to the output terminal of the inverter;
a fourth transistor having a control terminal, a first terminal, and a second terminal, wherein the control terminal of the fourth transistor is coupled to the input terminal of the inverter, the first terminal of the fourth transistor is coupled to the output terminal of the inverter, and the second terminal of the fourth transistor is coupled to a second power supply voltage, wherein the first power supply voltage is greater than the second power supply voltage.

5. The cache device according to claim 4, wherein the first power supply voltage is smaller than a sum of an absolute value of a threshold voltage of the third transistor and a threshold voltage of the fourth transistor.

6. The cache device according to claim 5, wherein the input voltage is greater than the first power supply voltage.

7. The cache device according to claim 4, wherein the third transistor is a PMOS transistor, and the fourth transistor is an NMOS transistor.

8. The cache device according to claim 1, wherein the second transistor is an NMOS transistor.

9. The cache device according to claim 2, wherein the low leakage current transistor is a low leakage current CMOS transistor.

10. The cache device according to claim 2, wherein the low leakage current transistor is a low leakage current IGZO (indium gallium zinc oxide) transistor.

11. An operation method of a cache device, wherein
the cache device comprises:
a first transistor having a control terminal, a first terminal, and a second terminal, wherein the first terminal is coupled to an input voltage, and the second terminal is coupled to a storage node;
an inverter having an input terminal and an output terminal, wherein the input terminal is coupled to the storage node; and
a second transistor having a control terminal, a first terminal, and a second terminal, wherein the first terminal is coupled to the output terminal of the inverter, and the second terminal is configured to output a read voltage,
the operation method comprising:
turning on the first transistor and turning off the second transistor during a write period so that the input voltage is stored in the storage node; and
turning off the first transistor and turning on the second transistor during a read period, and outputting a voltage of the output terminal of the inverter as the output voltage through the second terminal of the second transistor.

12. The operation method of the cache device according to claim 11, wherein the first transistor is a low leakage current transistor.

13. The operation method of the cache device according to claim 11, wherein the first transistor is used as a write transistor, the control terminal of the first transistor is coupled to a write word line, the first terminal of the first transistor is coupled to a write bit line, during the write period, a bias is applied to the control terminal of the first transistor to turn on the first transistor, and the input voltage is applied through the write bit line,
the second transistor is used as a read transistor, the control terminal of the second transistor is coupled to a read word line, the second terminal of the second transistor is coupled to a read bit line, during the read period, a bias is applied to the control terminal of the second transistor to turn on the second transistor, and the read voltage is output through the read bit line.

14. The operation method of the cache device according to claim 11, wherein the inverter comprises:
a third transistor having a control terminal, a first terminal, and a second terminal, wherein the control terminal of the third transistor is coupled to the input terminal of the inverter, the first terminal of the third transistor is coupled to a first power supply voltage, and the second terminal of the third transistor is coupled to the output terminal of the inverter;
a fourth transistor having a control terminal, a first terminal, and a second terminal, wherein the control terminal of the fourth transistor is coupled to the input terminal of the inverter, the first terminal of the fourth transistor is coupled to the output terminal of the inverter, and the second terminal of the fourth transistor is coupled to a second power supply voltage, wherein the first power supply voltage is greater than the second power supply voltage.

15. The operation method of the cache device according to claim 14, wherein in the inverter, the first power supply voltage is applied to the first terminal of the third transistor, wherein the first power supply voltage is smaller than a sum of an absolute value of a threshold voltage of the third transistor and a threshold voltage of the fourth transistor.

16. The operation method of the cache device according to claim 15, wherein the input voltage is greater than the first power supply voltage.

17. The operation method of the cache device according to claim 14, wherein the third transistor is a PMOS transistor, and the fourth transistor is an NMOS transistor.

18. The operation method of the cache device according to claim 11, wherein the second transistor is an NMOS transistor.

19. The operation method of the cache device according to claim 12, wherein the low leakage current transistor is a low leakage current CMOS transistor.

20. The operation method of the cache device according to claim 12, wherein the low leakage current transistor is a low leakage current IGZO transistor.
